(19) United States
(12) Patent Application Publication
(10) Pub. No.: US 2012/0145843 A1
(43) Pub. Date: Jun. 14, 2012

(54) Support Structure of a Digital Device

(76) Inventors: Chi-Pei Ho, Hsi-Chih City (TW); Chi-Dou Ho, Taipei City (TW)

(21) Appl. No.: 12/963,689

(22) Filed: Dec. 9, 2010

(51) Int. Cl. H05K 7/14

(52) U.S. Cl. 248/176.3

(57) ABSTRACT

A support structure of a digital device contains a holding unit including a tray member to place the digital device, the tray member including a circular hole disposed on a central portion thereof, a plurality of retaining recesses arranged around the hole on a front end of the tray member; an angle adjusting mechanism including a circular tab and a number of resilient locking devices attached around a peripheral side of the circular tab, such that the tab is fitted in the hole of the tray member of the holding unit so that the holding unit is rotated vertically or horizontally by using the angle adjusting mechanism; a supporting unit axially with the angle adjusting mechanism.

### BACKGROUND OF THE INVENTION

1. Field of the Invention

The present invention relates to supporting structure, and more particularly to a supporting structure of a digital device to place the digital device based on requirement.

2. Description of the Prior Art

A conventional digital device, such as a touch panel computer, a PDA, an electronic reader, is developed and used widely, and it is capable of being rotated horizontally or vertically to be portable and operated easily.

However, such a conventional digital device is easy to fall from a user's hand to be broken, when the user touches its screen carelessly. Besides, the digital device has to be held by the user's hand, therefore the user will feel uncomfortable after operating it for a long period of time. When the digital device is put on a desk, the user can not view the screen clearly because of a reflected light from the screen, and it is inconvenient for the user to touch the screen. If the digital device contacts with the desk or an object at a tilted angle, it slides easily and can not be adjusted toward a preferred operating angle, operating troublesomely.

The present invention has arisen to mitigate and/or obviate the afore-described disadvantages.

### SUMMARY OF THE INVENTION

The primary object of the present invention is to provide a supporting structure of a digital device of which the holding unit and the angle adjusting mechanism are fixed in a retaining manner, accordingly the holding unit is removed from the angle adjusting mechanism easily to be portable conveniently, and the hole of the tray member of the holding unit is grasped by the user's fingers to place the digital device securely and safely, preventing the digital device from sliding from the user's hand. Furthermore, the hole is applicable for various digital devices which are rotated horizontally or vertically. Also, the anti-slip cushion fixed in the four through orifices at four corners of the tray member matches with the protective pad to enhance anti-proof effect greatly.

Further object of the present invention is to provide supporting structure of a digital device of which the supporting unit is axially rotated to retractably contact with the back end of the holding unit and to be fitted on the peripheral side of the angle adjusting mechanism, and then the retracted supporting unit and the angle adjusting mechanism are held by the user so that the digital device is held stably and safely, thus preventing the digital device from sliding from the user's hand. In addition, the supporting unit is axially rotated toward the suitable angle to be supported on the desk, therefore the supporting unit and the digital device are rotated horizontally or vertically when they are held by the user or fixed on the desk.

Another object of the present invention is to provide supporting structure of a digital device that of which the supporting unit is formed in a C-shaped seat shape to be held easily, so the digital device is held and portable easily, and the supporting unit is capable of being hanged on a wall or other places to enhance usage.

To obtain the above objectives, supporting structure of a digital device provided by the present invention contains:

a holding unit including a tray member to place the digital device, the tray member including a circular hole disposed on a central portion thereof, a plurality of retaining recesses arranged around the hole on a front end of the tray member;

an angle adjusting mechanism including a circular tab and a number of resilient locking devices attached around a peripheral side of the circular tab, such that the tab is fitted in the hole of the tray member of the holding unit so that the holding unit is rotated vertically or horizontally by using the angle adjusting mechanism;

a supporting unit axially with the angle adjusting mechanism.

### BRIEF DESCRIPTION OF THE DRAWINGS

FIG. 1 is a perspective view showing the exploded components of a supporting structure of a digital device according to a first embodiment of the present invention;

FIG. 2 is a perspective view showing the exploded components of a half part of the supporting structure of the digital device according to the first embodiment of the present invention;

FIG. 3 is a perspective view showing the assembly of the supporting structure of the digital device according to the first embodiment of the present invention;

FIG. 4 is a cross sectional view showing the assembly of the supporting structure of the digital device according to the first embodiment of the present invention;

FIG. 5 is a perspective view showing the operation of a holding unit of the supporting structure of the digital device according the first embodiment of the present invention;

FIG. 6 is a perspective view showing the operation of a supporting unit of the supporting structure of the digital device according the first embodiment of the present invention;

FIG. 7 is a side plan view showing the operation of the supporting structure of the digital device according the first embodiment of the present invention;

FIG. 8 is a perspective view showing the operation of the supporting structure of the digital device according the first embodiment of the present invention;

FIG. 9 is a perspective view showing the exploded components of a supporting structure of a digital device according a second embodiment of the present invention;

FIG. 10 is a top plan view showing the operation of the supporting structure of the digital device according the second embodiment of the present invention;

FIG. 11 is a cross sectional view showing the operation of the supporting structure of the digital device according the second embodiment of the present invention;

FIG. 12 is a perspective view showing the assembly of a supporting structure of a digital device according a third embodiment of the present invention.

### DETAILED DESCRIPTION OF THE PREFERRED EMBODIMENTS

The present invention will be clearer from the following description when viewed together with the accompanying drawings, which show, for purpose of illustrations only, the preferred embodiment in accordance with the present invention.

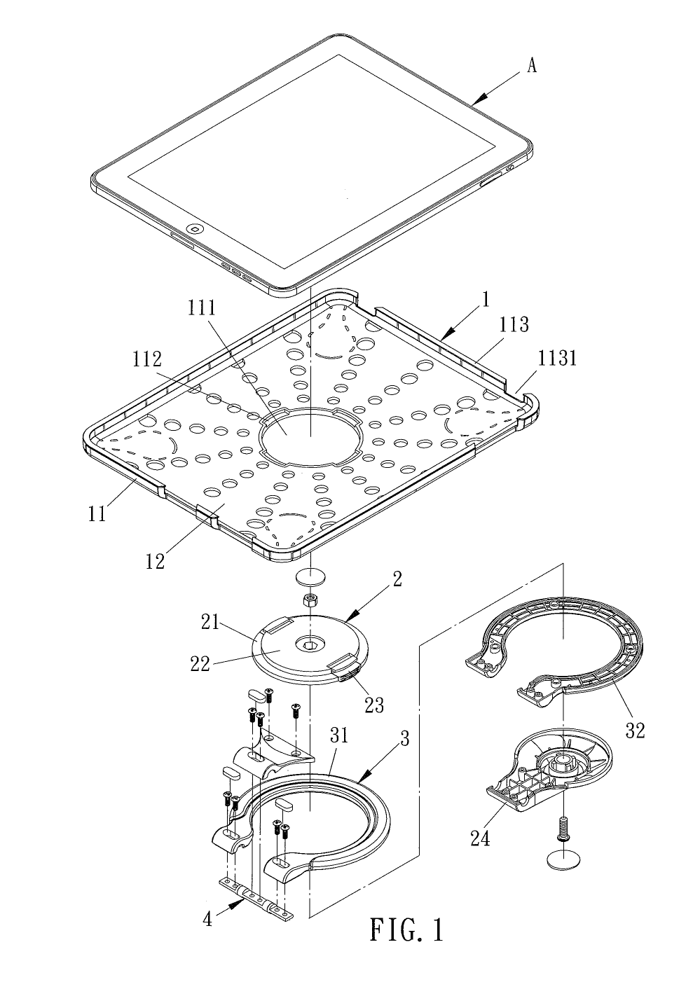

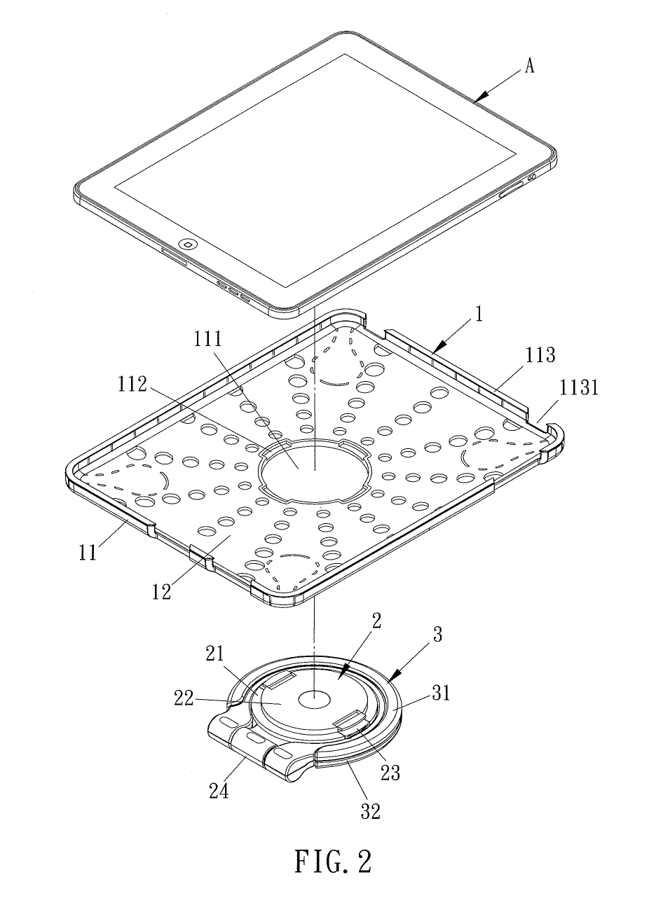

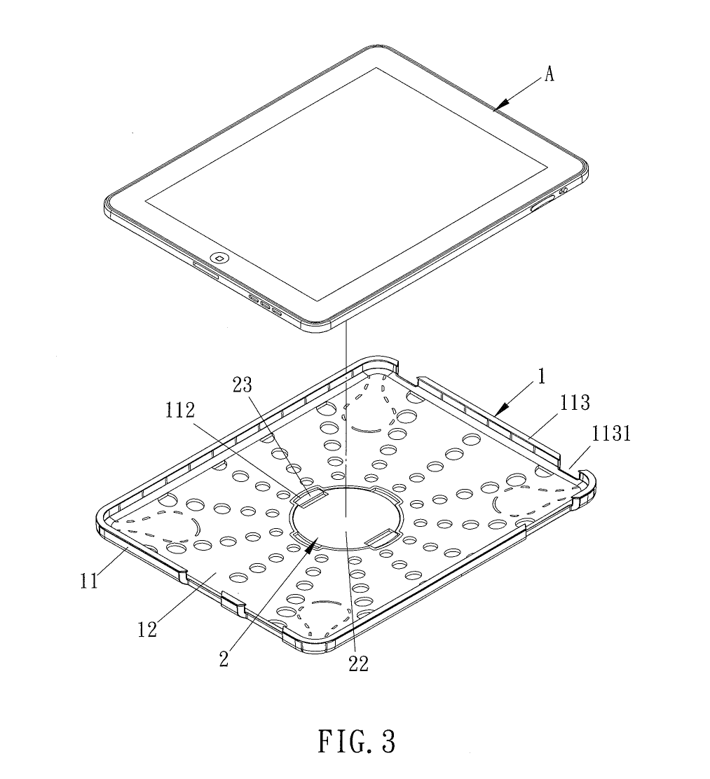

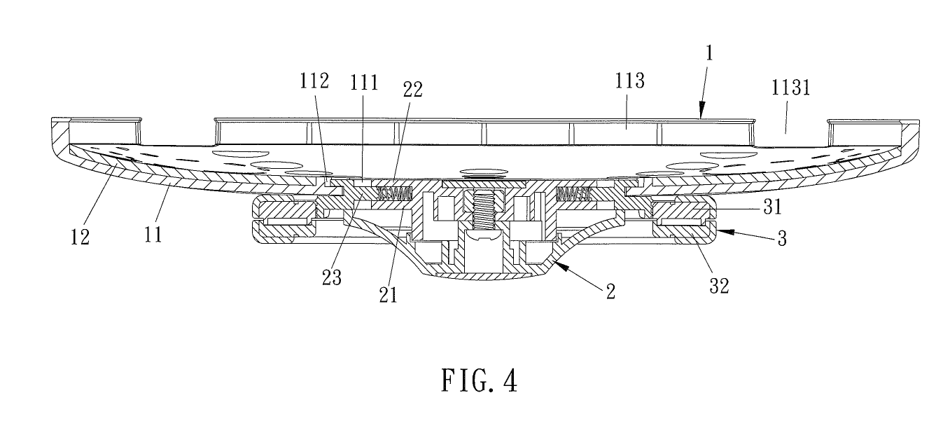

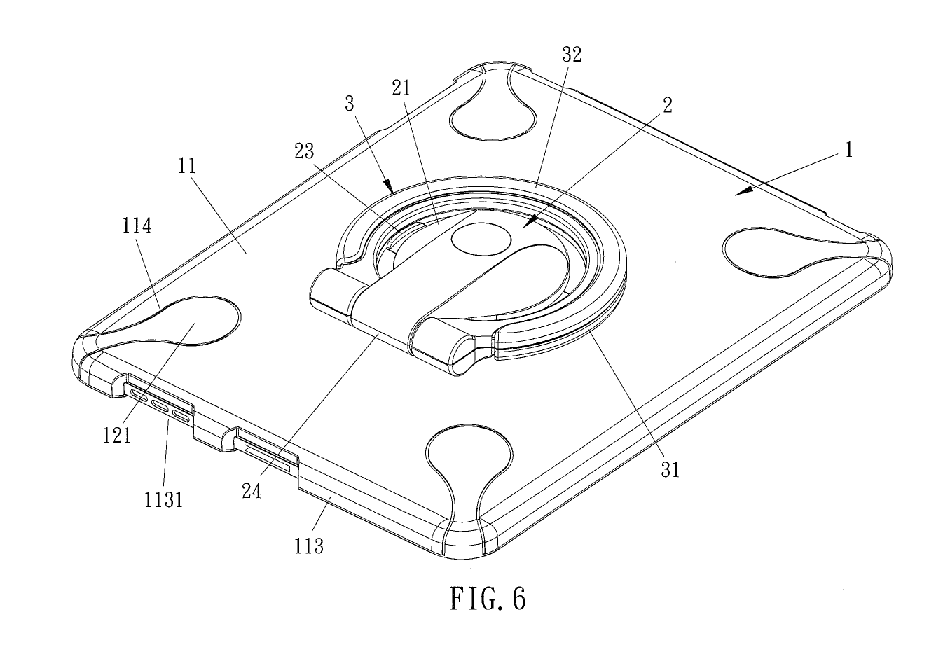

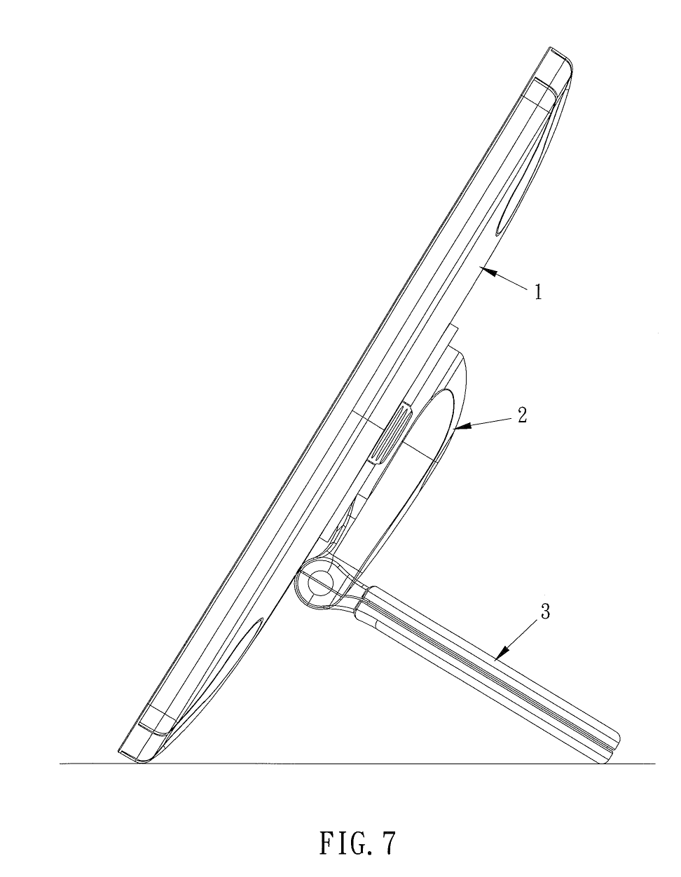

With reference to FIGS. 1-4, a support structure of a digital device according to a first embodiment of the present invention comprises a holding unit 1, an angle adjusting mechanism 2, and a supporting unit 3, wherein the holding unit 1 is comprised of a tray member 11 and a soft protective pad 12 fitted therein to place the digital device A, the tray member 11 includes a circular hole 111 disposed on a central portion thereof, four retaining recesses 112 arranged around the hole 111 on a front end of the tray member 11 evenly, and a peripheral rib 113 formed around a peripheral side thereof, the peripheral rib 113 includes a plurality of notches 1131 formed thereon. As shown in FIGS. 6 and 7, the tray member 11 includes four through orifices 114 fixed at four corners thereof respectively, and each through orifice 114 is used to position an anti-slip cushion 121 extending from the protective pad 12; the angle adjusting mechanism 2 includes a seat 21, a circular tab 22 extending from a front end of the seat 21, two oppositely resilient locking devices 23 attached around a peripheral side of the circular tab 22, an axial connecting portion 24 extending from one side of the seat 21 such that the tab 22 is fitted in the hole 111 of the tray member 11 of the holding unit 1, and the two resilient locking devices 23 are retained with two of the retaining recesses 112; the supporting unit 3 is formed in a C-shaped seat shape and includes a first semicircular loop 31 and a second semicircular loop 32 connected with the first semicircular loop 31, and the first and the second semicircular loops 31, 32 are made of a soft pad material; in the assembly, the axial connecting portion 24 of the angle adjusting mechanism 2 is fixed in an opening of the supporting unit 3 by using a post 4 so that the supporting unit 3 axially rotates relative to the angle adjusting mechanism 2.

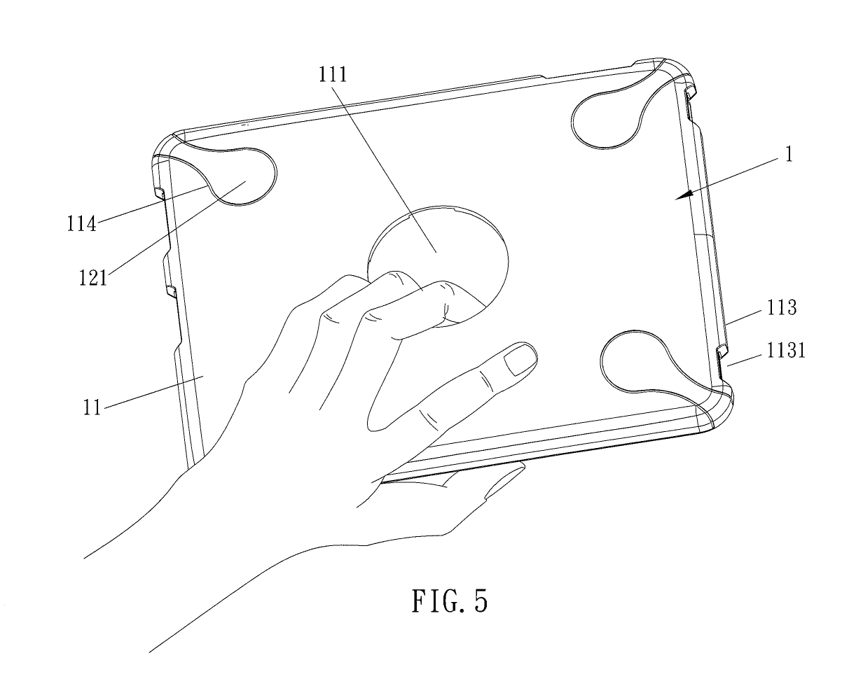

In operation, as illustrated in FIG. 5, the two resilient locking devices 23 of the angle adjusting mechanism 2 are pressed to disengage from the retaining recesses 112 of the tray member 11 of the holding unit 1, and then the holding unit 1 is removed from the angle adjusting mechanism 2 to place the digital device A thereon; and when a user holds the holding unit 1 to operate the digital device A, the hole 111 of the tray member 11 of the holding unit 1 is grasped by the user's fingers to hold the digital device A securely and safely, preventing the digital device A from sliding from the user's hand. Furthermore, due to the hole 111 is circular and fixed on the central portion of the tray member 11, it is applicable for various digital devices A which are rotated horizontally or vertically.

With reference to FIG. 6, the supporting unit 3 is axially rotated to retractably contact with a back end of the holding unit 1 and to be fitted on a peripheral side of the angle adjusting mechanism 2, and then the retracted supporting unit 3 is held by the user so that the digital device A is held stably and safely, thus preventing the digital device A from sliding from the user's hand. In addition, because the supporting unit 3 is formed in a C-shaped seat shape, it is also applicable for the various digital devices A which are rotated horizontally or vertically.

As illustrated in FIG. 7, when desiring to putting the supporting unit 3 on a desk, the supporting unit 3 is axially rotated toward a suitable angle to abut against the desk, and the first and the second semicircular loops 31, 32 made of the soft pad material rub against the desk to obtain an anti-proof effect, and the holding unit 1 becomes tilted at the suitable angle to put the digital device A, operating the digital device A conveniently.

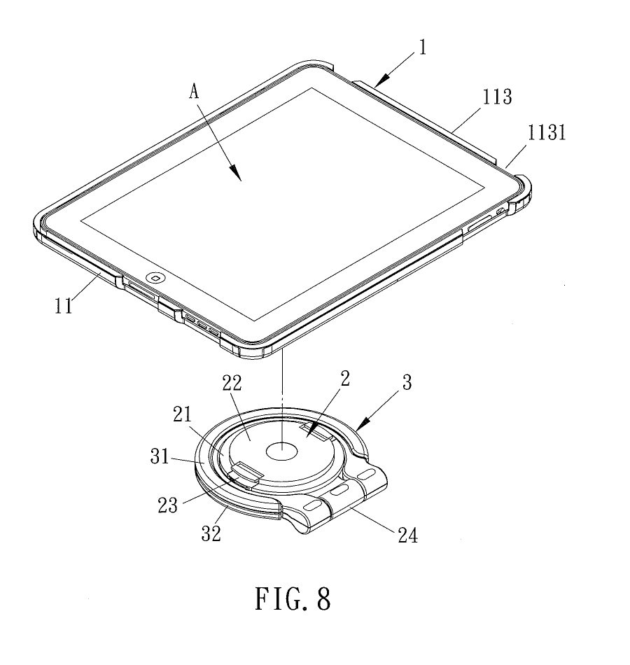

Referring to FIG. 8, when desiring to adjusting the digital device A toward a vertical or horizontal angle, the two resilient locking devices 23 of the angle adjusting mechanism 2 are pressed to disengage from the retaining recesses 112 of the tray member 11 of the holding unit 1 so that the holding unit 1 is removed from the angle adjusting mechanism 2 and is rotated 90 degrees, and then the tab 22 of the angle adjusting mechanism 2 is fitted in the hole 111 of the tray member 11 of the holding unit 1 so that the resilient locking devices 23 are retained with two of the retaining recesses 112, adjusting the digital device A toward the vertical or horizontal angle easily.

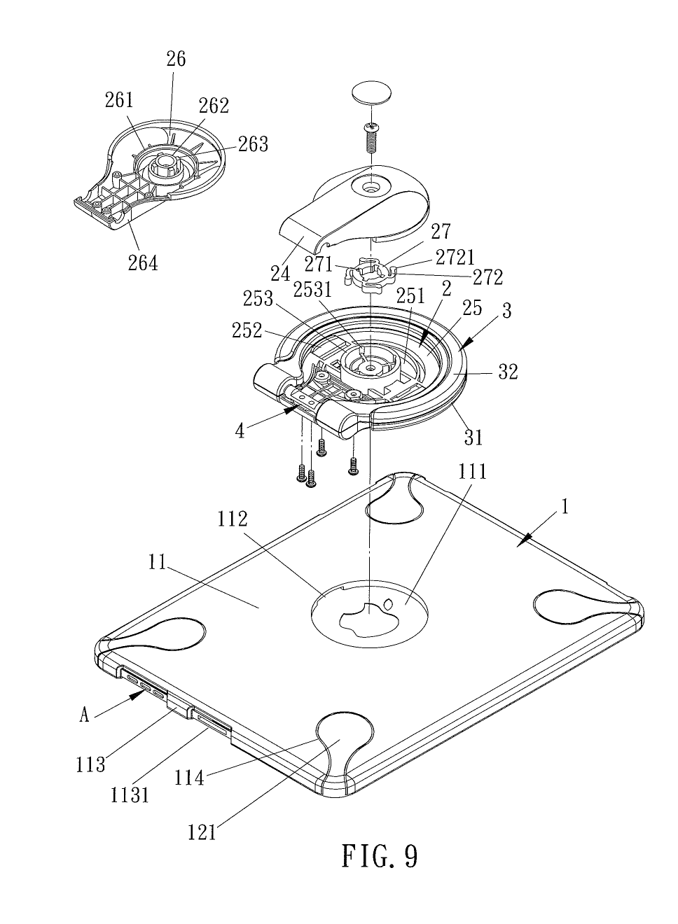

With reference to FIG. 9, a support structure of a digital device according to a second embodiment of the present invention comprises a holding unit 1 including a tray member 11, the tray member 11 includes a circular hole 111 disposed on a front end thereof, two opposite retaining recesses 112 arranged around the hole 111; a angle adjusting mechanism 2 comprised of a rotary disc 25, a coupling member 26, and a fixing member 27, the rotary disc 25 includes an annular projection 251 disposed on a front end thereof, and the projection 251 includes two opposite retainers 252 disposed on a peripheral side thereof to fit the projection 251 in the hole 111 of the tray member 11 of the holding unit 1 so that the retainers 252 are retained with the recesses 112 of the hole 111 of the tray member 11 of the holding unit 1 respectively; the rotary disc 25 includes an annular extension 253 form on a back end thereof, the extension 253 includes a number of arcuate cutouts 2531 arranged on an inner wall thereof equally, the coupling member 26 includes a fitting segment 261 fixed on a front end thereof to be fitted to the extension 253 of the rotary disc 25, and the fitting segment 261 includes a column 262 secured therein, the column 262 includes four locking protrusions 263 arranged therearound evenly, and the coupling member 26 includes an axial joining segment 264 extending from one side thereof and fixed in a mouth of a supporting unit 3 by ways of a post 4 so that the supporting unit 3 axially rotates relative to the angle adjusting mechanism 2, and the fixing member 27 is formed in a ring shape to be fitted on the column 262 of the coupling member 26, includes four indentations 261 equally formed around an inner surface thereof to retain with the four locking protrusions 263 of the column 262 of the coupling member 26 individually, and includes four spiral legs 272 extending from an outer surface thereof, and each leg 272 includes an arcuate engaging portion 2721 disposed on a distal end thereof to abut against and retain with the arcuate cutout 2531 so as to achieve a positioning purpose, thereby positioning the holding unit 1.

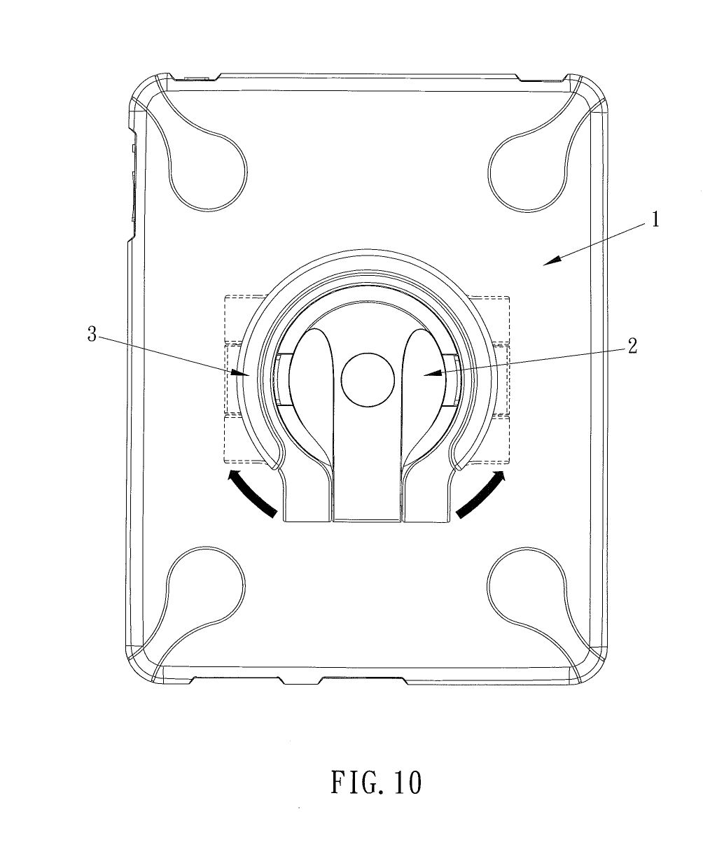

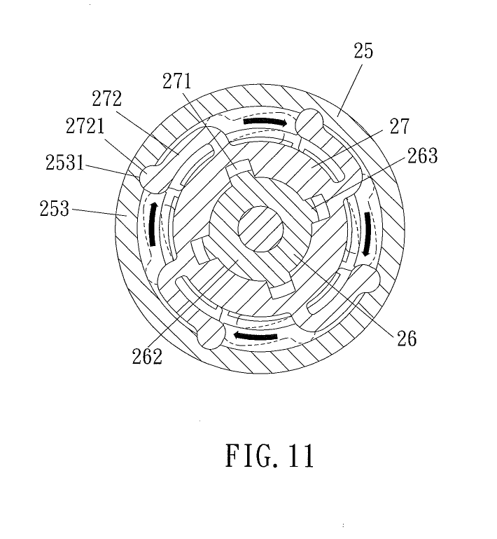

As desiring to adjusting the digital device A placed on the holding unit 1 as shown in FIGS. 10 and 11, the holding unit 1 is rotated in a clockwise or an anti-clockwise direction with the rotary disc 25 of the angle adjusting mechanism 2 so that the legs 272 of the fixing member 27 disengage from the cutouts 2531 of the extension 253 of the rotary disc 25 and slide along an inner wall of the extension 25 of the rotary disc 25, and after the holding unit 1 is rotated 90 degrees with the rotary disc 25, the engaging portions 2721 of the legs 272 of the fixing member 27 abut against and retain with the cutouts 2531 of the extension 253 of the rotary disc 25 again, thus adjusting the digital device A toward the vertical or horizontal angle easily.

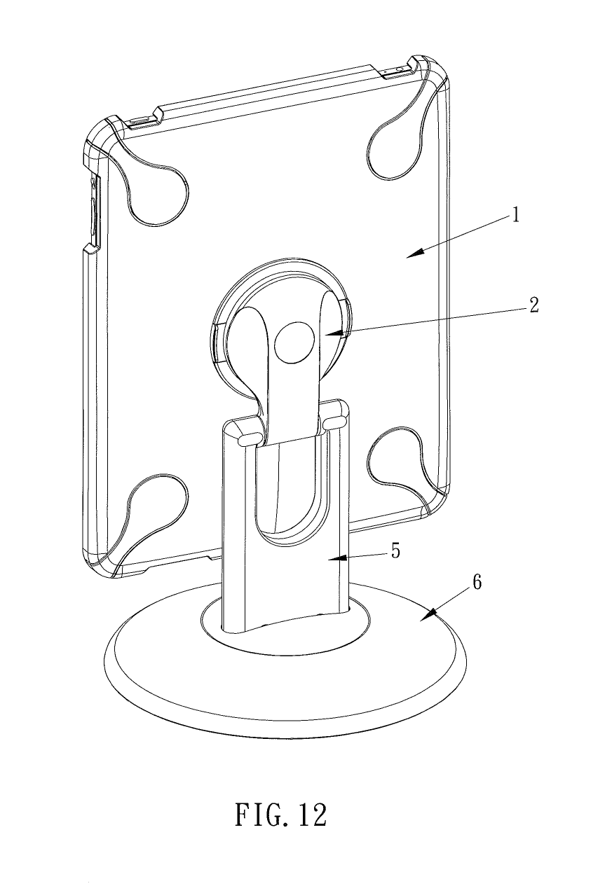

Referring to FIG. 12, a support structure of a digital device according to a third embodiment of the present invention comprises an angle adjusting mechanism 2 including a bearing member 5 axially connected therewith, and the bearing member 5 includes a counter weight block 6 axially coupled therewith to support a holding unit 1 and the angle adjusting mechanism 2 on the desk fixedly.

Thereby, the support structure of the digital device of the present invention has the following advantages:

1. The holding unit 1 and the angle adjusting mechanism 2 are fixed in a retaining manner, accordingly the holding unit 1 is removed from the angle adjusting mechanism 2 easily to be portable conveniently, and the hole 111 of the tray member 11 of the holding unit 1 is grasped by the user's fingers to place the digital device A securely and safely, preventing the digital device A from sliding from the user's hand. Furthermore, the hole 111 is applicable for various digital devices A which are rotated horizontally or vertically. Also, the anti-slip cushion 121 fixed in the four through orifices 114 at four corners of the tray member 11 matches with the protective pad 12 to enhance anti-proof effect greatly.

2. The supporting unit 3 is axially rotated to retractably contact with the back end of the holding unit 1 and to be fitted on the peripheral side of the angle adjusting mechanism 2, and then the retracted supporting unit 3 and the angle adjusting mechanism 2 are held by the user so that the digital device A is held stably and safely, thus preventing the digital device A from sliding from the user's hand. In addition, the supporting unit 3 is axially rotated toward the suitable angle to be supported on the desk, therefore the supporting unit 3 and the digital device A are rotated horizontally or vertically when they are held by the user or fixed on the desk.

3. The supporting unit 3 is formed in a C-shaped seat shape to be held easily, so the digital device A is held and portable easily, and the supporting unit 3 is capable of being hanged on a wall or other places to enhance usage.

While we have shown and described various embodiments in accordance with the present invention, it is clear to those skilled in the art that further embodiments may be made without departing from the scope of the present invention.

What is claimed is:

1. A support structure of a digital device comprising:
a holding unit including a tray member to place the digital device, the tray member including a circular hole disposed on a central portion thereof, a plurality of retaining recesses arranged around the hole on a front end of the tray member;
an angle adjusting mechanism including a circular tab and a number of resilient locking devices attached around a peripheral side of the circular tab, such that the tab is fitted in the hole of the tray member of the holding unit so that the holding unit is rotated vertically or horizontally by using the angle adjusting mechanism;
a supporting unit axially with the angle adjusting mechanism.

2. The support structure of the digital device as claimed in claim 1, wherein the tray member includes a peripheral rib formed around a peripheral side thereof, the peripheral rib includes a plurality of notches formed thereon, and the tray member also includes four through orifices fixed at four corners thereof respectively, and each through orifice is used to position an anti-slip cushion extending from the protective pad.

3. The support structure of the digital device as claimed in claim 1, wherein the angle adjusting mechanism includes an axial joining segment extending from one side thereof and fixed in the supporting unit by ways of a post so that the supporting unit axially rotates relative to the angle adjusting mechanism.

4. The support structure of the digital device as claimed in claim 1, wherein the angle adjusting mechanism is comprised of a rotary disc, a coupling member, and a fixing member, the rotary disc includes an annular projection disposed on a front end thereof, and the projection includes a plurality of retainers disposed on a peripheral side thereof to fit the projection in the hole of the tray member of the holding unit so that the retainers are retained with the recesses of the hole of the tray member of the holding unit respectively; the rotary disc also includes an annular extension form on a back end thereof, the extension includes a number of arcuate cutouts arranged on an inner wall thereof equally, the coupling member includes a fitting segment fixed on a front end thereof to be fitted to the extension of the rotary disc, and the fitting segment includes a column secured therein, the column includes a number of locking protrusions arranged therearound evenly, the fixing member is formed in a ring shape to be fitted on the column of the coupling member, includes a plurality of indentations equally formed around an inner surface thereof to retain with the locking protrusions of the column of the coupling member individually, and includes a number of spiral legs extending from an outer surface thereof, and each leg includes an engaging portion disposed on a distal end thereof to abut against and retain with the cutout.

5. The support structure of the digital device as claimed in claim 4, wherein the coupling member includes an axial joining segment extending from one side thereof and fixed in the supporting unit by ways of the post so that the supporting unit axially rotates relative to the angle adjusting mechanism.

6. The support structure of the digital device as claimed in claim 1, wherein the supporting unit is formed in a C-shaped seat shape and includes a first semicircular loop and a second semicircular loop connected with the first semicircular loop, and the first and the second semicircular loops are made of a soft pad material.

7. The support structure of the digital device as claimed in claim 1, wherein the angle adjusting mechanism includes a bearing member axially connected therewith, and the bearing member includes a counter weight block axially coupled therewith.
